(19) United States
(12) Patent Application Publication
(10) Pub. No.: US 2024/0142512 A1
(43) Pub. Date: May 2, 2024

(54) SEMICONDUCTOR DEVICE TESTING

(71) Applicant: Texas Instruments Incorporated, Dallas, TX (US)

(72) Inventors: Zhi Peng Feng, Chengdu (CN); Ren Hui Fan, Chengdu (SC); Alfred Griffin, Dallas, TX (US); He Lin, Frisco, TX (US)

(21) Appl. No.: 17/978,170

(22) Filed: Oct. 31, 2022

(51) Int. Cl. G01R 31/265; G01R 31/26

(52) U.S. Cl. CPC G01R 31/2656; G01R 31/2601

(57) ABSTRACT

A semiconductor device testing system, with a platform for supporting a semiconductor substrate, a light emitting system directed toward the platform, a controller, coupled to the light emitting system and adapted to selectively alter an operational parameter of the light emitting system, and a tester configured to characterize an electrical parameter of an electrical device formed in or over the semiconductor substrate while the electrical device is illuminated by one or more wavelengths of light emitted by the light emitting system under direction of the controller.

### CROSS-REFERENCE TO RELATED APPLICATION

Not applicable.

### BACKGROUND

Semiconductor devices, typically packaged into integrated circuits (ICs), pervade all manners of electronic devices. Efforts to improve semiconductor device testing often evaluate structure and device reliability, consistency, and operability, any one or more of which may factor into device cost and yield and have been and are a part of past and ongoing IC evolution. Conventional methods for semiconductor device testing, or characterization, include direct current (DC) current-voltage (I-V) testing, alternating current (AC) capacitance-voltage (CV) testing, and others. These methods may identify some reliability failure causes, while other causes are insufficiently identified.

Accordingly, there may be a need or desire to provide improved semiconductor device manufacturing and testing. This document provides examples that may improve on certain of the above concepts, as detailed below.

### SUMMARY

In one example, there is a semiconductor device testing system. The system includes a platform for supporting a semiconductor substrate, a light emitting system directed toward the platform, a controller, coupled to the light emitting system and adapted to selectively alter an operational parameter of the light emitting system, and a tester configured to characterize an electrical parameter of an electrical device formed in or over the semiconductor substrate while the electrical device is illuminated by one or more wavelengths of light emitted by the light emitting system under direction of the controller.

In another example, there is a method of testing a semiconductor device. The method includes, in a first step, measuring an electrical parameter of the semiconductor device while concurrently illuminating the semiconductor device with light having first optical characteristics and in a second step, measuring the electrical parameter of the semiconductor device while concurrently illuminating the semiconductor device with light having second optical characteristics differing from the first optical characteristics.

Other aspects and examples are also disclosed and claimed.

### BRIEF DESCRIPTION OF THE DRAWINGS

FIG. 1 illustrates a semiconductor wafer having a plurality of instances of an IC, the IC including an electrical device.

FIG. 2 is a diagram of an IC testing system adapted to characterize the electrical device of FIG. 1 while illuminating the electrical device with optical energy.

FIG. 3 is a flowchart of an example operational method for the FIG. 2 IC testing system that may be used to characterize the electrical device of FIG. 1 using the IC testing system of FIG. 2.

FIG. 4 is a testing plot of an example of electrical stimuli and test measures from the FIG. 3 method for an example electrical device.

FIG. 5 is a data set from the FIG. 3 method that may represent an acceptable instance of the electrical device.

### DETAILED DESCRIPTION

Examples of the present disclosure relate to semiconductor device manufacturing and testing. Various disclosed examples may be beneficially applied to testing electrical devices related to an integrated circuit to determine if such devices meet criteria for proper or expected operational characteristics. While such examples may be expected to provide data that are useful for determining whether such electrical devices may be packaged and sold, or should be scrapped, no particular result is a requirement unless explicitly recited in a particular claim.

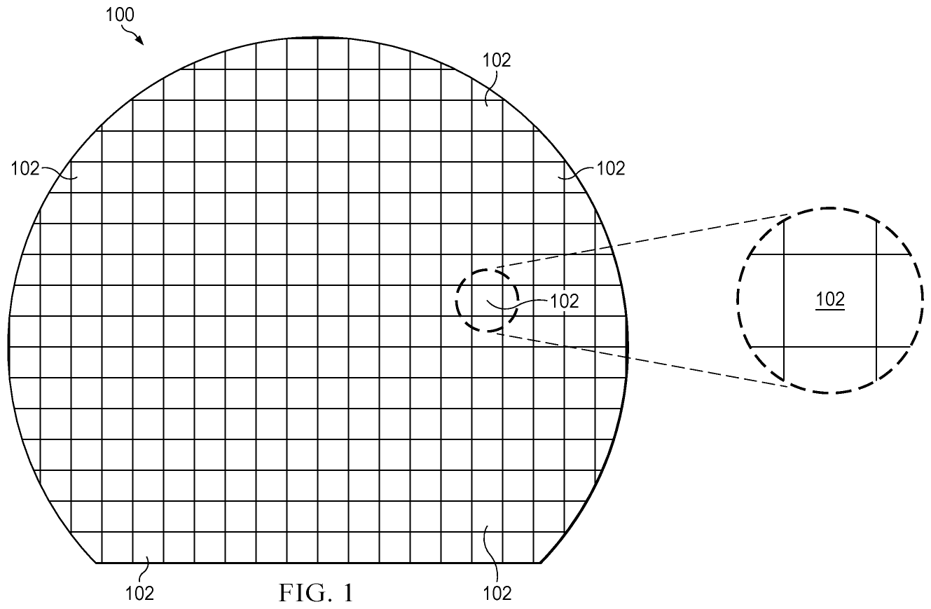

FIG. 1 illustrates a semiconductor wafer 100, typically formed from silicon. Portions of the semiconductor wafer 100 are concurrently processed to form respective same-shaped regions, each providing a respective IC 102 (only some are labeled to simplify the Figure). In an example, each IC 102 may be a discrete device, plural discrete devices, or an IC having functionality instead of, or including but also extending beyond, discrete devices, for example as memory storage, an application specific IC (ASIC), or a processor with one or more memory circuits. When the semiconductor wafer 100 is still in the FIG. 1 general form, e.g. prior to singulation of the IC 102 instances, some or all of the ICs 102 on the wafer may be tested, for example by a manual, or partially- or fully-automated testing apparatus and process, that position a probe or probes to electrically contact a singular (or a few) instance(s) of the IC 102. Once an IC 102 (or set of ICs) is fully tested, the testing apparatus advances to probe a next individual IC 102 (or set of ICs) and again executes the testing steps, and this process repeats desirably for each IC 102, so that ultimately all ICs 102 on the wafer 100, or a predefined subset, are tested.

Once testing is complete, actions may be taken with respect to each IC 102 based on its test results, for example by separating (sometimes called singulating) each of the ICs 102 from the semiconductor wafer 100 and from one another, with the test results associated with each IC 102 then used for disposition of each IC 102. For example, for any IC 102 that fully fails its test, the IC can be discarded or tested further, for example in a further effort to identify either design or process issues that caused the test failure, and with a goal of reducing or eliminating the cause of those issues. Non-failing ICs, however, can be separated into different groups depending on a performance score. Each different performing group is then identified for potential different treatment, for example for sales into different end applications based on such performance.

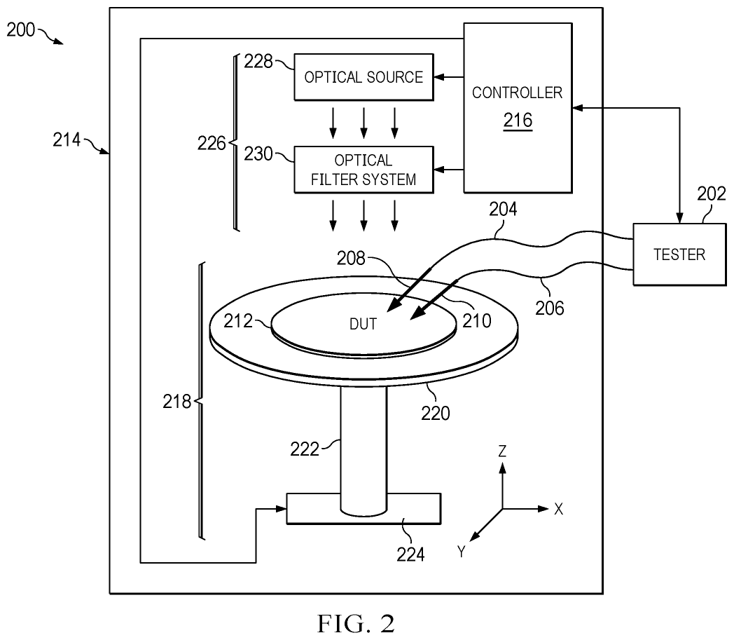

FIG. 2 is a diagram of an IC testing system 200. The testing system 200 includes a tester 202. The tester 202 couples to at least a first cable 204, and also potentially to a second cable 206, which respectively couple to a first and second probe 208 and 210. The probes 208 and 210 are positioned to contact a device under test (DUT) 212. The DUT 212 may be, for example, the FIG. 1 semiconductor wafer 100, and the probes 208 and 210 may be positioned to contact, and facilitate testing of, an IC 102 on that wafer 100. Generally, the tester 202 includes various circuits and functionality for testing one, or typically more than one, electrical parameter of the DUT 212, via the cables 204 and 206 and the probes 208 and 210. The tested parameter may include, for example, inductance, capacitance, and resistance, and the tester 202 may sometimes be referred to as an LCR meter, L for inductance, C for capacitance, R for resistance. The tester 202 also may test the parameter(s) at a specified frequency, or over a range of frequencies.

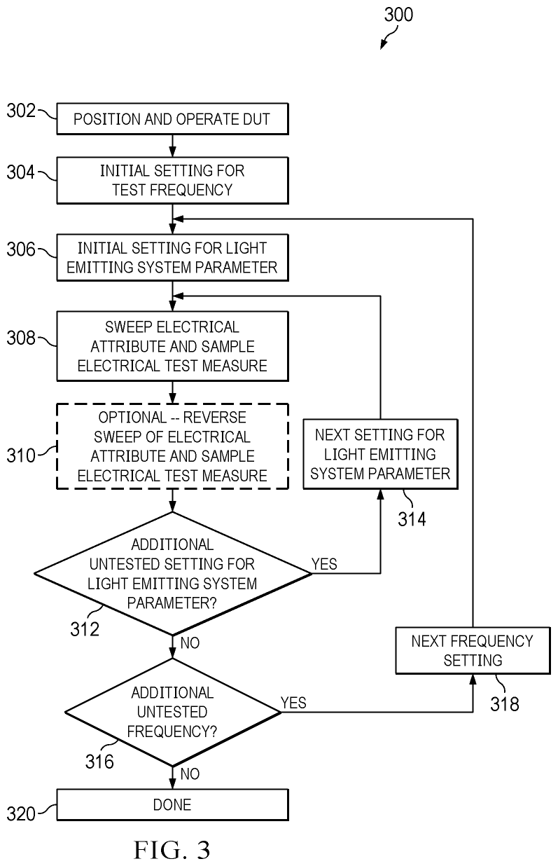

The tester 202 is also situated proximate, or coupled to, a collection of apparatus, which sometimes may be enclosed in, or otherwise physically situated relative to, a support structure 214, such as a cabinet, frame, or the like. The support structure 214 supports a controller 216 and a DUT positioning system 218. The controller 216 may be a dedicated circuit, functional apparatus, or a computing device, with adequate circuitry for controlling the overall operations of the testing system 200. For example, the controller 216 may be a computational device including a central processing unit (CPU) or other processor, computer readable media, such as memory, accessible by the CPU and for storing data and/or programming instructions, and input/output interfacing to couple with portions of the testing system 200, and potentially beyond, for example with communications to a network or other computations system, either locally or distant. The controller 216 may operate in conjunction with, and/or be coupled (e.g., bidirectionally) to, the tester 202. Accordingly, the controller 216 is programmed with instructions which, when executed by the CPU, perform various operations in combination with the functionality of the tester 202 for testing the DUT 212, as further described later in connection with FIGS. 3 through 5.

The DUT positioning system 218 includes structure for retaining and moving the DUT 212. For example, the DUT positioning system 218 includes a platform 220, on which the DUT 212 is either directly located, or supported by intermediate structures, which may include shapes and apparatus to accommodate the perimeter (e.g., circular) of the DUT 212 and also to assure its alignment and positional retention during testing. The platform 220 is physically supported by a shaft 222 that is coupled to an electromechanical actuator 224. In the illustrated example, the electromechanical actuator 224 is operable to move the shaft 222 three dimensionally (shown by x-y-z axes), which correspondingly moves the platform 220 and the DUT 212. Such movement can assist with loading and unloading the DUT 212 from the DUT positioning system 218, and also with re-positioning the DUT 212 in connection with properly aligning the tips (not separately shown) of the probes 208 and 210 to make the desired contact to an IC 102 on the DUT 212.

The support structure 214 also may include a light emitting system 226, including an optical source 228, and optionally an optical filter system 230, for projecting a light source toward the DUT 212 during testing. Either the output of the optical source 228, or the output of the optional optical filter system 230, may be within a range of 30 mm to 300 mm of the DUT 212. The optical source 228 may have a broad spectrum (e.g., a white light source) or a narrower spectrum (e.g., a laser). The optical filter system 230 may include one, or more than one, optical filter for filtering light received from the optical source 228, thereby passing a selected wavelength band of light to the DUT 212. The selected wavelength can be longpass (low pass in terms of optical frequency), short pass (high pass in terms of frequency), or bandpass, with the latter potentially selecting a relatively narrow bandwidth. Variation in the selected wavelength can be by choosing one of different filters, or by the repositioning of a single filter, such as a linear variable bandpass filter, whereby its position relative to the optical source 228 determines the light wavelength band that is passed. The controller 216 is coupled to the optical source 228, and optionally also the optical filter system 230, so that each can be controlled to select or vary among different light-related or optical parameters, such as light intensity or light bandwidth, thereby adapting that parameter to affect the light from the light emitting system 226, and as that resulting light impinges on the DUT 212.

FIG. 3 is a flowchart of an example operational method 300, e.g. using the FIG. 2 IC testing system 200, commencing with a step 302. In the step 302, the DUT (e.g., FIG. 2 DUT 212) is positioned in the testing system 200, for example affixed to, or relative to, the platform 220. The DUT 212 is then operated, for example by coupling a system power supply and clock signal to it. Next, the method 300 continues from the step 302 to a step 304.

In the step 304, an initial setting is established for a test frequency at which the testing is to be conducted. For example, the method 300 may include testing at a number N of different test frequencies, F(1), F(2), . . . , F(N), in which case then the step 304 establishes a first of those frequencies, F(1). A test frequency is a frequency at which a periodic stimulus, such as a voltage or current, is directed to the DUT 212. The method 300 then continues from the step 304 to a step 306.

In the step 306, an initial setting is established for an optical parameter of the light emitting system 226. For example, if the step 306 optical parameter is light intensity, then the method 300 may include testing at a number M of different light intensities L(1), L(2), . . . , L(M), in which case then the step 306 establishes a first of those intensities, L(1). Each value L(x) may be referred to as a “setting” of the optical parameter. The first intensity may be selected and controlled by the controller 216. As an example, the first intensity L(1) may be to disable the optical source 228, creating a dark state (other than potential ambient light in the vicinity) on the DUT 212. In other examples, the step 306 may be other selectable factors that affect the light passing from the light emitting system 226 to the DUT 212. For example, different light sources, having different optical characteristics such as center wavelength, bandwidth and/or spectral distribution, may be selected for the optical source 228. As another example, different filters, or a different bandpass for a given filter, may be selected from the optical filter system 230. Further, any of these selections may be made by control of the controller 216. In any event, once the initial intensity setting is established, the method 300 continues from the step 306 to a step 308.

In the step 308, and under the step 306 established optical parameter L(x) and at the step 304 established frequency F(y), the tester 202 sweeps across a range of an electrical stimulus, while the probes 208 and 210 contact appropriate testing points (e.g., contacts of an IC 102) on the DUT 212. The electrical stimulus may be selected from various options, including, as examples, voltage, current, and frequency. For example, if the electrical stimulus is voltage, then the voltage may be swept across a range of the expected safe operating range for the IC 102, such as between 0 V and 5.0 V (or −5.0 V to +5.0V), while for example other electrical stimuli are maintained at a same initial value. As the electrical stimulus is swept, an electrical test measure is taken, via the probes 208 and 210, at various times (sampled) and the results are recorded, for example in storage (e.g., memory) in either the tester 202 alone or in communication with the controller 216 (or to other computational equipment). The electrical test measure(s) also may include any of the electrical stimuli, or may further include capacitance, resistance, inductance, admittance, or conductance, which may be directly measured or determined based on one or more other measures (for example, determining impedance based on current and voltage). Next, the method 300 continues from the step 308 to a step 310.

The step 310 is an optional step and accordingly is shown in FIG. 3 in a dashed rectangle. The step 310 generally repeats the step 308, but sweeps the step 308 electrical stimulus in opposite direction as compared to the step 308 sweep direction. In the previous example where the step 308 sweeps voltage as the electrical stimulus and from low to high (e.g., 0 V to 5 V), then the step 310 sweeps voltage as the electrical stimulus and from high to low (e.g., 5 V to 0 V), while again sampling and storing the same electrical test measure type as from the step 308. Accordingly, the results from the step 310 may be contrasted from that of step 308, to determine if there is any hysteresis effect in the comparison. Next, the method 300 continues from the step 310 to a step 312.

The step 312 is a conditional step to implement looping in the method 300 for the plural different M optical parameters (including different settings of a same parameter, such as light intensity), with the first of the settings being the L(1) that was first initialized in the step 306. In the current example, where the step 306 initialized a light intensity optical parameter, then the step 312 evaluates whether there is a desired additional setting for that parameter, that has not yet been tested. In the earlier example of intensity as the step 306 light emitting system optical parameter, recall the further example of the step 306 setting that parameter to disable the optical source 228, creating a dark state. Accordingly, in the first instance of the step 312, it may be determined that an additional setting L(2), for example of an intensity other than a dark state, is desired and not yet tested, in which case the step 312 directs the method flow to a step 314. In another instance of the step 312, if all M desired settings of the light emitting system parameter have been tested, the step 312 directs the method flow to a step 316.

The step 314 alters the light emitting system optical parameter L(x) to a next setting L(x+1). In the prior example, where the light emitting system parameter is intensity and where the initial parameter setting L(1) in the step 304 was zero (a dark state), then the first instance of the step 314 may set the parameter to a non-zero value. Thereafter, the method 300 returns to the step 308, so that it is executed, followed by the optional step 310 and the step 312, using the altered setting from the preceding instance of the step 314. For example, if that instance of the step 314 sets the parameter (intensity) to a non-zero value, such as a particular lux (luminous flux per unit area), then the step 308 again sweeps the electrical stimulus (e.g., voltage) while measuring samples (e.g., capacitance) with that amount of light intensity directed (and potentially filtered) to the DUT 212. Optionally thereafter, the step 310 reverses the sweep and repeats the sampling. Next, the step 312 again determines whether there is another untested setting for the light emitting system parameter, such as another non-zero intensity value, other than the one set by the previous instance of the step 314. This looping will continue the number of times required to test all M of the optical parameter settings, to include the initial setting set by the step 306. Eventually, when all such desired optical parameter settings have been tested, the method 300 continues to the step 316.

The step 316 is a conditional step to implement looping in the method 300 for the plural different N test frequencies, with the first of the frequencies being the F(1) that was first initialized in the step 304. Accordingly, the step 316 evaluates whether there is a desired additional test frequency at which the DUT 212 has not yet been tested. If another test frequency is desired and not yet tested, the step 316 directs the method flow to a step 318. If all N frequencies have been tested, the step 316 directs the method flow to a step 320.

The step 318 alters the frequency F(y) to a next setting F(y+1). Thereafter, the method 300 returns to the step 306, so that after it the remaining test steps are executed, for example starting again with an initialized optical parameter L(1) and swept electrical stimulus, with an optional opposite direction sweep, and repeating for up to N optical parameters, all at the next frequency F(y+1). Moreover, those steps may repeat yet against for another frequency setting F(y+2), and so forth, until the steps are repeated for a final frequency setting F(N). At that point, the step 316 detects no additional untested frequency, at which point the method 300 concludes at a step 320.

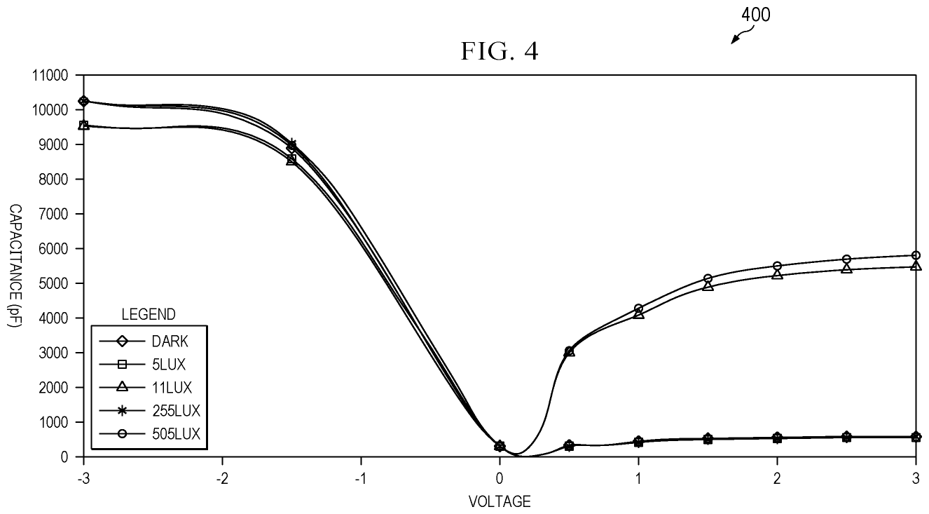

FIG. 4 is a testing plot 400 of an example of an electrical stimulus and test measures from the FIG. 3 method 300. In FIG. 4, the horizontal axis depicts the step 306 sweeping of voltage (in volts) as its electrical stimulus, and the vertical axis depicts the sampled electrical test measures of capacitance (in pF), all achieved for a single step 304 frequency F(x). Moreover, as indicated by the LEGEND, there are a total of five different optical parameters (light intensities), and by example having respective intensities of zero (dark), 5 lux, 11 lux, 255 lux, and 505 lux. The step 308 electrical stimulus sweeps for each intensity, that is, the step 312 loops the method steps back to step 308 for each intensity following the first intensity. Further, for the FIG. 4 plot 400, the optional step 308 is omitted, as no reverse direction sweep is included. Also in FIG. 4, there is not a loop from step 316 to earlier in the method, in that only a single frequency is shown in the FIG. 4 example. FIG. 4 demonstrates that the results of the test may indicate that the sampled electrical test measure may vary based on different optical parameters, for example with a first area of capacitance being similar for light intensity at 11 lux and 505 lux (and rising with positive voltage to approximately 5,000 to 6,000 pF), and with a second area of capacitance being similar for light intensity at a dark state, and at 5 lux, and 255 lux (and remaining relatively linear or rising moderately with positive voltage, to approximately 500 pF). The difference between the first area and the second area may indicate a proper operational difference in the responsiveness of the DUT to the different light intensity alone, or as a DUT anomaly (potential defect).

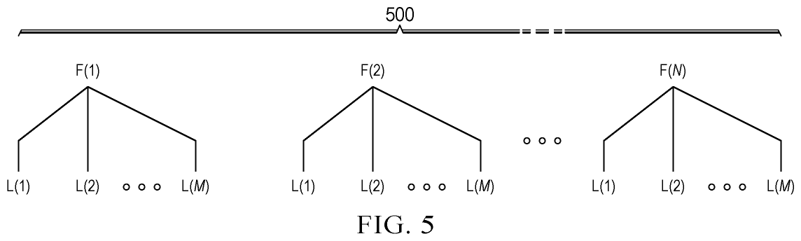

FIG. 5 is a data set 500 from the FIG. 3 method 300 testing a DUT, and with the test results from M different optical parameters for each of N different frequencies. For example, the FIG. 4 testing plot 400 may be represented by the FIG. 5 first frequency data subset F(1), which is shown to be tested at first optical parameter L(1) (e.g., light at a dark state), a second optical parameter L(2) (e.g., 5 lux), and so forth up to an Nth optical parameter, which in FIG. 4 is L(5) with the light at 505 lux. Each of the remaining FIG. 5 frequency data subsets, F(2), . . . , F(N) is likewise tested for each of the M different optical parameters. Also in this regard, in one example, the data set 500 corresponds to a baseline or reference DUT, for example taken using method 300, and with respect to a DUT 212 that is otherwise expected (or separately tested) to be properly performing or complying with the intended specifications. A separate data set (akin to data set 500) is taken for each additional DUT. Thereafter, the findings of each data set are compared to the baseline data set 500, using comparison metrics as may be ascertained by one skilled in the art, and for example by comparing each different optical parameter performance, that is, comparing the results of the baseline DUT at F(1) and L(1) to another tested DUT at F(1) and L(1), then comparing the baseline to the other tested DUT at F(2) and L(2), and so forth for all N frequencies and all M optical parameters. If the comparison results in significant deviation(s), the deviation(s) can be evaluated, for example compared to a threshold difference from the baseline, whereby exceeding the threshold difference may indicate potential defects in a tested DUT.

The illustrated examples provide a system and methodology relating to semiconductor device manufacturing and testing. In an example, the system and methodology perform semiconductor device testing, such as probe testing, while imposing a light condition on the DUT, the condition involving for example light intensity and/or light bandwidth. Testing is performed and repeated, with each test having a corresponding but different light condition imposed on the DUT. The changes in light bandwidth can impose wide spectrum lighting, narrow spectrum lighting, or single wavelength lighting. Further, the testing can sweep an electrical parameter, or multiple parameters, either in a single direction, and/or in a reverse direction, while an electrical test measure is captured and recorded. The resultant test measures, particularly when values in a first set corresponding to a first light condition diverge from values in a second set corresponding to a second light condition, may reveal vulnerabilities, potential, or actual fault conditions in the tested DUT, for example relating to various manufacturing processes or chemistries, include factors such as mobile ions, heavy metals, count doping, plasma, static charging, etc. Once such matters are identified, the manufacturing process/recipe used to manufacture the IC may be modified, in view of the identified issue(s), so as to reduce or eliminate its effects in a thereby-improved manufacturing process. As still another benefit, various inventive aspects can be implemented in a variety of configurations. For example, the FIG. 3 method 300 may include alternative or additional steps, particularly in combination with other testing apparatus or methods/method steps. Different levels of configuration details have been presented herein, for example the use of different electrical stimuli, electrical test measures, optional reverse sweeping, and optical filters, and the inventive scope may include still others as contemplated or may be determined by one skilled in the art from the teachings of this document. Accordingly, additional modifications are possible in the described examples, and others are possible, within the scope of the following claims.

What is claimed is:

1. A semiconductor device testing system, comprising:
a platform for supporting a semiconductor substrate;
a light emitting system directed toward the platform;
a controller, coupled to the light emitting system and adapted to selectively alter an operational parameter of the light emitting system; and
a tester configured to characterize an electrical parameter of an electrical device formed in or over the semiconductor substrate while the electrical device is illuminated by one or more wavelengths of light emitted by the light emitting system under direction of the controller.

2. The system of claim 1 wherein an output of the light emitting system is spaced apart from the platform by a distance in a range from about 30 mm to about 300 mm.

3. The system of claim 1 wherein the controller is adapted to control the tester.

4. The system of claim 1 wherein the electrical parameter is at least one of capacitance, resistance, inductance, admittance, and conductance.

5. The system of claim 1 wherein the tester is adapted to sweep an electrical stimulus across a range beginning at a first value and ending at a second value, the electrical stimulus adapted to be applied to the electrical device.

6. The system of claim 5 wherein the tester is further adapted to sweep the electrical stimulus beginning at the second value and ending at the first value.

7. The system of claim 1 wherein the operational parameter of the light emitting system is selected from a list including intensity and bandwidth.

8. The system of claim 1 wherein the light emitting system includes a wavelength filter between an optical source and the platform.

9. The system of claim 8 wherein the controller is adapted to select a filter characteristic of the wavelength filter.

10. The system of claim 1 wherein the platform is configured to receive a semiconductor wafer.

11. A method of testing a semiconductor device, comprising:
in a first step, measuring an electrical parameter of the semiconductor device while concurrently illuminating the semiconductor device with light having first optical characteristics; and
in a second step, measuring the electrical parameter of the semiconductor device while concurrently illuminating the semiconductor device with light having second optical characteristics differing from the first optical characteristics.

12. The method of claim 11 wherein the first optical characteristics include a first light intensity and the second optical characteristics include a second light intensity different from the first light intensity.

13. The method of claim 12 wherein the first light intensity is zero lux and the second light intensity is non-zero lux.

14. The method of claim 12 wherein the first step and the second step both include exposing the semiconductor device with a light source spaced apart from the semiconductor device by a distance in a range from about 30 mm to about 300 mm.

15. The method of claim 11 and further including stimulating the semiconductor device according to a same frequency during the first and second steps.

16. The method of claim 11 and further including repeating the first and second steps for a plurality of instances of the semiconductor device formed in or over a semiconductor substrate, and for each instance of the plurality of instances stimulating the semiconductor device according to a different respective frequency.

17. The method of claim 16 and further including comparing a first measured electrical parameter from the first step corresponding to a first instance in the plurality of instances with a first measured electrical parameter from the first step corresponding to a second instance in the plurality of instances.
